(19) United States
(12) Patent Application Publication
(10) Pub. No.: US 2019/0107569 A1
(43) Pub. Date: Apr. 11, 2019

(54) DIGITAL CURRENT MEASUREMENT FOR IN-SITU DEVICE MONITORING

(71) Applicant: QUALCOMM Incorporated, San Diego, CA (US)

(72) Inventors: David Kidd, San Diego, CA (US); Ardavan Moassessi, San Diego, CA (US); Angelo Pinto, San Diego, CA (US); Albert Kumar, San Jose, CA (US); Yi Lou, San Diego, CA (US); Bipin Duggal, Irvine, CA (US); Amar Gulhane, Cedar Park, TX (US); Michael Bourland, Austin, TX (US); Mustafa Badaroglu, Kessel-Lo (BE); Paul Penzes, San Diego, CA (US)

(21) Appl. No.: 15/730,486

(22) Filed: Oct. 11, 2017

(51) Int. Cl. G01R 31/02; G01R 31/28; G01R 31/36; H01L 21/66

(52) U.S. Cl. CPC G01R 31/025; H01L 22/34; G01R 31/3648; G01R 31/2851

(57) ABSTRACT

Aspects of the disclosure includes a transistor-under-test (TUT) to charge/discharge a capacitor; changing an oscillation state when a capacitor voltage crosses a threshold and turning OFF the TUT; discharging the capacitor using the TUT; commencing precharging the capacitor after detecting the capacitor reaches a transition voltage; commencing discharging the capacitor after a precharger time delay; sustaining a relaxation oscillator waveform, wherein the relaxation oscillator waveform is based on turning OFF/ON the TUT; and generating a digital representation of a TUT current associated with a relaxation oscillator period of the relaxation oscillator waveform. For example, a measurement tile includes a pulse generator to sustain the relaxation oscillator waveform with the relaxation oscillator period associated with an inverse TUT current; and a precharger charging a capacitor and the TUT charging/discharging the capacitor, wherein the relaxation oscillator waveform is based on turning OFF/ON the TUT in accordance with discharging and charging the capacitor.

### TECHNICAL FIELD

This disclosure relates generally to the field of digital current measurement, and, in particular, to digital current measurement for in-situ device monitoring.

### BACKGROUND

Transistor production on wafers may result in undesirable process variations which degrade electronics performance. Thus, transistor characteristics, such as transistor current, need to be measured to assess process variations on the wafers. Current electronics designs may include special wafers which incorporate non-operational circuitry which measure transistor characteristics (e.g. transistor current) on the wafer. However, such special wafers cannot be sold since the non-operational circuitry prevents full functionality.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the disclosure provides a current measurement system for in-situ device. Accordingly, a method for digital current measurement for monitoring an in-situ device, the method including: using a transistor under test (TUT) to charge or discharge a capacitor; changing an oscillation state when a capacitor voltage of the capacitor crosses a threshold and turning OFF the TUT; discharging the capacitor using the TUT; commencing precharging the capacitor after detecting the capacitor reaches a transition voltage; commencing discharging the capacitor after a precharger time delay; sustaining a relaxation oscillator waveform, wherein the relaxation oscillator waveform is based on turning OFF and turning ON the TUT; and generating a digital representation of a TUT current, wherein the TUT current is associated with a relaxation oscillator period of the relaxation oscillator waveform.

In one example, the threshold is half of a maximum value of a drain voltage of the TUT. The method may further include using a conversion equation to convert the relaxation oscillator period to an inverse current of the TUT. In one example, the inverse current of the TUT is a reciprocal of the TUT current. The conversion equation may have the form of a linear equation. And, in one example, the conversion equation is as follows: T_{osc}=C ΔV I⁻¹+t_{ckt}, wherein T_{osc} is the relaxation oscillator period, C ΔV is a slope of the conversion equation, and t_{ckt} is a circuit offset time due to a precharger time delay. C is a capacitance value of the capacitor and ΔV is the change of voltage of the capacitor. In one example, the conversion equation is based on a calibration process which uses a reference current or a circuit simulation model.

In one example, the in-situ device includes a plurality of negative channel metal oxide semiconductor (NMOS) transistors. And, the in-situ device may include a plurality of positive channel metal oxide semiconductor (PMOS) transistors. In one example, a precharger is used to precharge the capacitor.

Another aspect of the disclosure provides a measurement tile including: a transistor under test (TUT); a pulse generator to sustain a relaxation oscillator waveform with a relaxation oscillator period associated with an inverse current of the TUT; a capacitor coupled to the TUT; a precharger coupled to the capacitor and to the TUT, the precharger for charging the capacitor and the TUT for charging or discharging the capacitor, wherein the relaxation oscillator waveform is based on turning OFF and turning ON the TUT in accordance with discharging and charging the capacitor. In one example, the measurement tile further includes an output divider to output a modified relaxation oscillator waveform, wherein the modified relaxation oscillator waveform is the relaxation oscillator waveform with the relaxation oscillator period modified, and wherein the output divider is coupled to the capacitor. In one example, the modified relaxation oscillator waveform is inputted to a counter, the counter to output a digital current measurement of the TUT.

In one example, the pulse generator includes a combinational logic to provide a clock input in accordance with the TUT; a flip flop to receive the clock input; and an inverter coupled to the flip flop to form an inverting feedback loop such that the output state of the flip flop changes each time the clock on the flip flop is pulsed. In one example, the inverting feedback loop sustains the relaxation oscillator waveform in accordance with an ON/OFF state of the TUT. In one example, a drain voltage output from the precharger is coupled to a drain terminal of the TUT. In one example, the drain voltage output is coupled to the capacitor at a first capacitor terminal. In one example, the drain voltage output is inputted to the combinational logic and is inputted to an output divider, wherein the output divider outputs a modified relaxation oscillator waveform. In another example, the pulse generator may contain combinational logic that controls asynchronous set and reset pins of a flip flop, with the clock pin being tied to ground. The set and reset pins can control the output state of the flip flop, and thereby control the precharger and TUT.

In one example, the modified relaxation oscillator waveform is the relaxation oscillator waveform with its associated relaxation oscillator period modified. In one example, the combinational logic includes one or more of an AND gate, a NAND gate, an OR gate and/or a NOR gate coupled to each other in accordance to whether the TUT is a negative channel metal oxide semiconductor (NMOS) TUT or a positive channel metal oxide semiconductor (PMOS) TUT. In one example, the modified relaxation oscillator waveform is inputted to a counter, the counter to output a digital current measurement of the TUT. In one example, the transistor under test (TUT) comprises a plurality of transistors under test (TUTs). In one example, a select signal is used to select one of the plurality of transistors under test (TUTs) for current measurement.

Another aspect of the disclosure provides an apparatus for digital current measurement for monitoring an in-situ device, the apparatus including: means for charging or discharging a capacitor, wherein the capacitor is coupled to a transistor under test (TUT); means for changing an oscillation state when a capacitor voltage of the capacitor crosses a threshold and for turning OFF the TUT; means for discharging the capacitor using the TUT; means for commencing precharging the capacitor after detecting the capacitor reaches a transition voltage; means for commencing discharging the capacitor after a precharger time delay; means for sustaining a relaxation oscillator waveform, wherein the relaxation oscillator waveform is based on turning OFF and turning ON the TUT; and means for generating a digital representation of a TUT current, wherein the TUT current is associated with a relaxation oscillator period of the relaxation oscillator waveform.

Another aspect of the disclosure provides a computer-readable medium storing computer executable code, operable on a device including at least one processor and at least one memory coupled to the at least one processor, wherein the at least one processor is configured to implement digital current measurement for monitoring an in-situ device, the computer executable code including: instructions for causing a computer to charge or discharge a capacitor using a transistor under test (TUT); instructions for causing the computer to change an oscillation state when a capacitor voltage of the capacitor crosses a threshold and turning OFF the TUT; instructions for causing the computer to discharge the capacitor using the TUT; instructions for causing the computer to commence precharging the capacitor after detecting the capacitor reaches a transition voltage; instructions for causing the computer to commence discharging the capacitor after a precharger time delay; instructions for causing the computer to sustain a relaxation oscillator waveform, wherein the relaxation oscillator waveform is based on turning OFF and turning ON the TUT; and instructions for causing the computer to generate a digital representation of a TUT current, wherein the TUT current is associated with a relaxation oscillator period of the relaxation oscillator waveform.

These and other aspects of the invention will become more fully understood upon a review of the detailed description, which follows. Other aspects, features, and embodiments of the present invention will become apparent to those of ordinary skill in the art, upon reviewing the following description of specific, exemplary embodiments of the present invention in conjunction with the accompanying figures. While features of the present invention may be discussed relative to certain embodiments and figures below, all embodiments of the present invention can include one or more of the advantageous features discussed herein. In other words, while one or more embodiments may be discussed as having certain advantageous features, one or more of such features may also be used in accordance with the various embodiments of the invention discussed herein. In similar fashion, while exemplary embodiments may be discussed below as device, system, or method embodiments it should be understood that such exemplary embodiments can be implemented in various devices, systems, and methods.

### BRIEF DESCRIPTION OF THE DRAWINGS

FIG. 1 illustrates a short-range layout effect example for a transistor.

FIG. 2 illustrates a long-range layout effect example with a transistor in a dense uniform array.

FIG. 3 illustrates an example of a measurement tile with a transistor under test (TUT).

FIG. 4 illustrates an example of a negative channel metal oxide semiconductor (NMOS) digital relaxation oscillator.

FIG. 5 illustrates an example of a positive channel metal oxide semiconductor (PMOS) digital relaxation oscillator.

FIG. 6 illustrates an example of a negative channel metal oxide semiconductor (NMOS) digital relaxation oscillator before connection to a plurality of NMOS transistors under test (TUTs).

FIG. 7 illustrates an example of a negative channel metal oxide semiconductor (NMOS) digital relaxation oscillator after connection to a plurality of NMOS transistors under test (TUTs).

FIG. 8 illustrates an example of a negative channel metal oxide semiconductor (NMOS) digital relaxation oscillator after connection to a plurality of NMOS transistors under test (TUTs) and with an external voltage source.

FIG. 9 illustrates an example of a measurement tile with two reference transistors.

FIG. 10 illustrates an example measurement circuit for generating a digital measurement of transistor under test (TUT) current.

FIG. 11 illustrates an example flow diagram for digital current measurement for monitoring an in-situ device.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

In the electronics industry, transistors are fundamental constituents of electronic circuitry. For example, an integrated circuit or semiconductor wafer for some useful application may include a plurality of transistors integrated in a monolithic semiconductor material, for example, silicon. In one aspect, economic viability of an integrated circuit or semiconductor wafer depends on efficient and repeatable transistor production techniques. Consequently, transistor production on semiconductor wafers should be monitored and controlled carefully to ensure reasonable production yield. In one aspect, production yield is the percentage of manufactured electronic devices which successfully achieve their performance requirements. Production yield may depend on the semiconductor manufacturing process used to produce the electronic devices. In general, a carefully controlled process, i.e., with minimal process variations, results in improved production yield.

In one example, transistor production on integrated circuits or semiconductor wafers may have undesirable process variations which degrade electronic device performance. Thus, certain transistor characteristics, such as transistor current, may need to be monitored to assess process variations on the wafers or integrated circuits. Current electronic designs may include special wafers which incorporate non-operational circuitry which measure transistor characteristics (e.g., transistor current) on the wafer. However, such special wafers cannot be sold since the non-operational circuitry prevents full functionality. Thus, this limitation drives a need for in-situ (i.e., on site) device monitoring. In one example, the present disclosure relates to a transistor measurement system for in-situ device monitoring for operational circuitry.

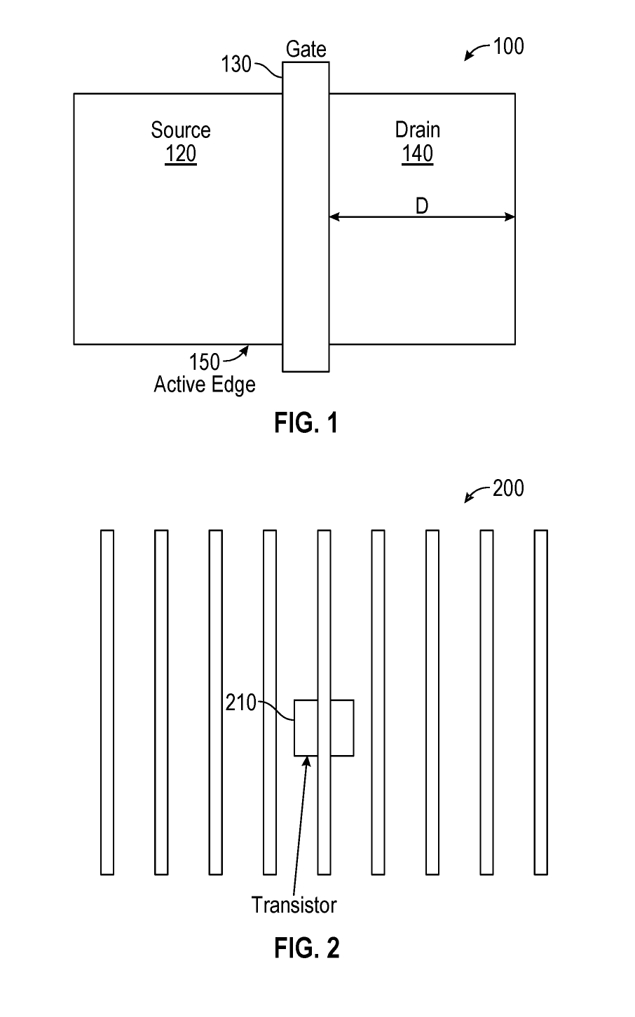

In one aspect, integrated circuit layout effects may alter transistor parameters such as threshold voltage or mobility which may result in a change in transistor current. Integrated circuit layout effects on a transistor may include short-range layout effects and long-range layout effects. For example, short-range layout effects may include features such as distance to active area, distance to polysilicon cut, distance between gate and active edge, distance from active edge to implant edge or well edge, etc. In one example, short-range layout effects in 10 nm technology may be related to layout geometries that are typically less than 1 micron (10⁻⁶ meter) distance from the transistor. In one example, 10 nm technology includes semiconductor devices with minimum feature sizes as low as 10 nm. FIG. 1 illustrates a short-range layout effect example 100 for a transistor. In the example of FIG. 1, the transistor includes a source 120, a gate 130 and a drain 140. Also shown is a distance D. The distance D is measured from the gate to an active edge 150. The distance D may be subject to a shallow trench isolation stress effect which may cause a mobility variation. As shown in FIG. 1, the distance D is represented by the length of the illustrated arrow. In one example, mobility is a semiconductor performance parameter which relates carrier (e.g., electron or hole) velocity to electric field strength in the semiconductor.

For example, long-range layout effects may include pattern density of transistor active area and polysilicon around the transistor of interest over a distance of a few microns and long-range gradients across a die or wafer over a distance of hundreds of microns up to a few centimeters (10⁻² meter) in range. FIG. 2 illustrates a long-range layout effect example 200 with a transistor 210 in a dense uniform array (versus a sparsely populated non-uniform local gradient). In one example, a long-range pattern density effect may affect integrated circuit lithography and therefore may affect the transistor current.

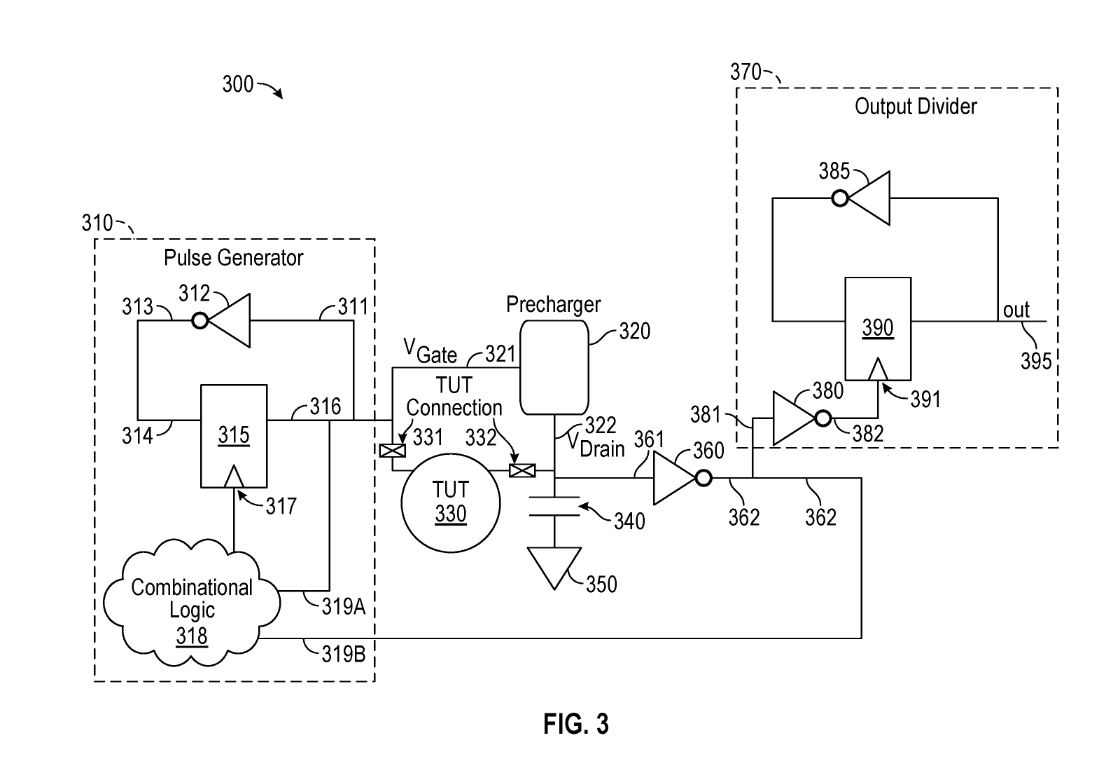

FIG. 3 illustrates an example 300 of a measurement tile with a transistor under test (TUT) 330. In one example, a pulse generator 310 includes a first inverter 312, a first flip flop 315 and combinational logic 318. For example, the first inverter 312 includes a first inverter output 313 which is connected to a first flip flop input 314 (i.e., input of the first flip flop 315). Also shown in FIG. 3 is a first flip flop output 316 (i.e., output of the first flip flop 315) which is connected to a first inverter input 311 (i.e., input of the first inverter 312). In addition, the first flip flop 315 has a first clock input 317 from an output of combinational logic 318. In addition, the combinational logic 318 includes a first combinational logic input 319A connected to the first flip flop output 316 and a second combinational logic input 319B connected to a second inverter output 362 (i.e., output of a second inverter 360). In one example, the combinational logic 318 may be different for a negative channel metal oxide semiconductor (NMOS) transistor under test (TUT) and a positive channel metal oxide semiconductor (PMOS) transistor under test (TUT) since the NMOS TUT may have a logical transition from ONE level to ZERO level and the PMOS TUT may have a logical transition from ZERO level to ONE level. For example, the NMOS TUT may require a ONE level on its gate terminal to be active and the PMOS TUT may require a ZERO level on its gate terminal to be active. Thus, in the one example, the combinational logic 318 drives the first clock input 317 of the first flip flop 315 differently according to the TUT type; that is, according to whether it is a NMOS or a PMOS.

In one example, the first flip flop output 316 is a relaxation oscillator waveform. The relaxation oscillator waveform includes a relaxation oscillator frequency or a relaxation oscillator period. The relaxation oscillator frequency is a reciprocal of the relaxation oscillator period. And, the relaxation oscillator period is a reciprocal of the relaxation oscillator frequency.

Next, the first flip flop output 316 is also connected to a gate voltage input (V_{Gate}) 321, a precharger 320 and a first TUT connection 331. The first TUT connection 331 is connected to a gate terminal of a transistor under test (TUT) 330. A drain voltage output (V_{Drain}) 322 from the precharger 320 is connected to a second TUT connection 332. The second TUT connection 332 is connected to a drain terminal of the TUT 330. As shown in FIG. 3, a capacitor 340 is connected to the drain voltage output (V_{Drain}) 322 at a first capacitor terminal (of the capacitor 340) and is connected to a ground 350 at a second capacitor terminal (of the capacitor 340). The drain voltage output (V_{Drain}) 322 is also connected to a second inverter input 361 of the second inverter 360. A second inverter output 362 (of the second inverter 360) is connected to the second combinational logic input 319B and an input of an output divider 370.

In one example, the output divider 370 includes a third inverter 380, a second flip flop 390 and a fourth inverter 385. The second inverter output 362 connects to the third inverter input 381 (i.e., input of the third inverter 380). In one example, the third inverter input 381 is an input of the output divider 370. The third inverter 380 includes a third inverter output 382 which is connected to a second clock input 391of the second flip flop 390. In one aspect, the output divider 370 may lower an output frequency in half and may also reduce duty cycle distortion in an output waveform. In one example, the output waveform is the relaxation oscillator waveform which is modified by, for example, lowering its associated relaxation oscillator frequency. The relaxation oscillator frequency is the reciprocal of the relaxation oscillator period. The output (labeled as out 395) of the output divider 370 is a modified relaxation oscillator waveform.

In one example, there may be zero or more output divider stages. In one example, the third inverter 380 may reduce loading on the second inverter 360. In one example, the first flip flop 315 and the second flip flop 390 are asynchronous reset flip flops that are held in a reset state when the measurement tile is not enabled.

One skilled in the art would understand that the components listed herein for the example 300 of the measurement tile with a transistor under test (TUT) are examples and the types of components and/or its quantity may vary within the spirit and scope of the present disclosure. And, it is understood that other components (although not explicitly listed herein) may be included as part of the example 300 of the measurement tile with the transistor under test (TUT). One skilled in the art would also understand that the connections of the various components as shown in the example of FIG. 3 are not exclusive. That is, other connections between the various components shown in FIG. 3 are also within the spirit and scope of the present disclosure.

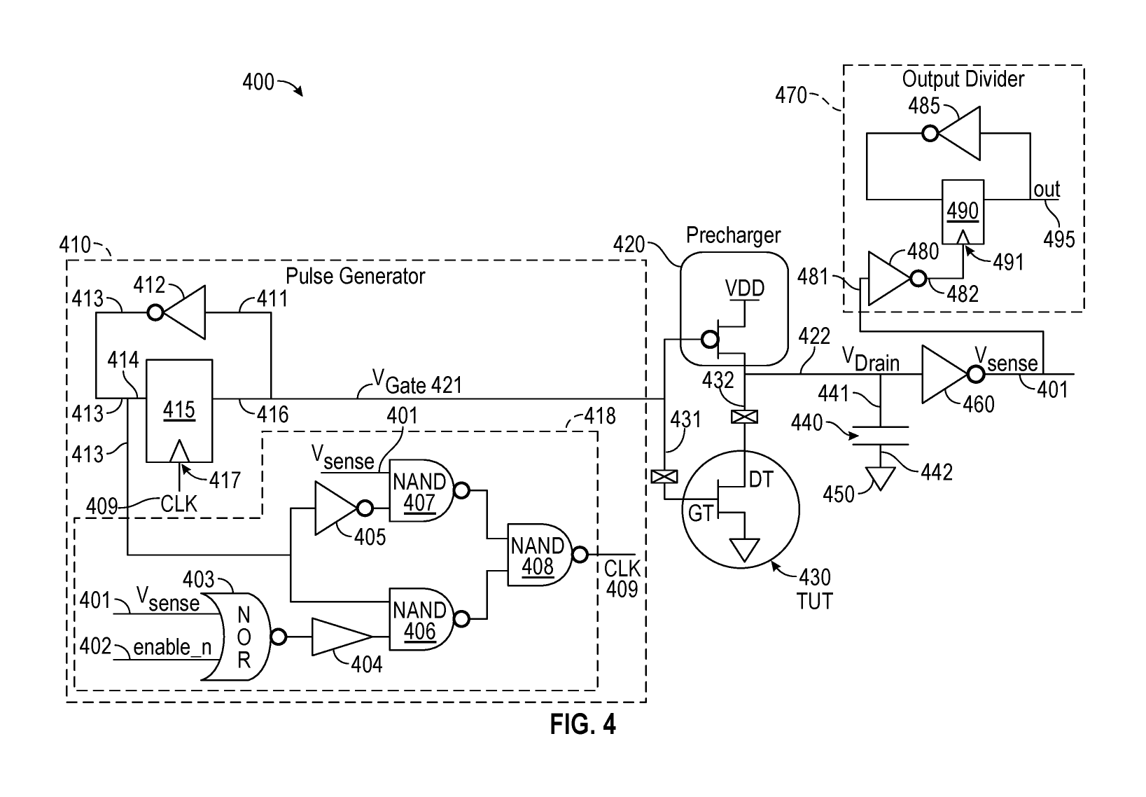

FIG. 4 illustrates an example of a negative channel metal oxide semiconductor (NMOS) digital relaxation oscillator 400. In one example, a pulse generator 410 includes a first inverter 412, first flip flop 415 and combinational logic 418. For example, a first inverter output 413 (i.e., output of the first inverter 412) is connected to a first flip flop input 414 (i.e., input of the first flip flop 415). As shown in FIG. 4, a first flip flop output 416 (i.e., output of the first flip flop 415) is connected to a first inverter input 411 (i.e., input of the first inverter 412). In addition, the first flip flop 415 includes a first clock input 417 which is from an output of the combinational logic 418.

In one example, the first flip flop output 416 is a relaxation oscillator waveform. The relaxation oscillator waveform includes a relaxation oscillator frequency or a relaxation oscillator period. The relaxation oscillator frequency is a reciprocal of the relaxation oscillator period. And, the relaxation oscillator period is a reciprocal of the relaxation oscillator frequency.

In one example, the combinational logic 418 may include one or more of the following components: a NOR gate 403, a delay element 404, an internal inverter 405, a first NAND gate 406, a second NAND gate 407, a third NAND gate 408, and a clock 409. In the example of FIG. 4, the NOR gate 403 includes with a first NOR input (Vₛₑₙₛₑ) 401 and a second NOR input (enable_n) 402. In one example, the delay element 404 sets a precharger time delay by its delay characteristics. In the example of FIG. 4, the first inverter output 413 is inputted to the internal inverter 405. In the example of FIG. 4, the first NAND gate 406 includes two inputs: a first input is connected to the delay element 404 and a second input is connected to the first inverter output 413. In the example of FIG. 4, the second NAND gate 407 includes two inputs: a first input is connected to first NOR input (Vₛₑₙₛₑ) 401, and a second input is connected to an output of the internal inverter 405. In the example of FIG. 4, the third NAND gate 408 includes two inputs: a first input is connected to an output of the first NAND gate 406 and a second input is connected to an output of the second NAND gate 407. In the example of FIG. 4, the clock 409 is an output of the third NAND gate 408, and the clock 409 is inputted to the first flip flop 415 through the first clock input 417.

One skilled in the art would understand that the components listed herein for the combinational logic 418 are examples and the types of components and/or its quantity may vary within the spirit and scope of the present disclosure. And, it is understood that other components (although not explicitly listed herein) may be included as part of the combinational logic 418. One skilled in the art would also understand that the connections of the various components of the combinational logic 418 as shown in the example of FIG. 4 is not an exclusive one. That is, other connections between the various components of the combinational logic 418 are also within the spirit and scope of the present disclosure.

In the example of FIG. 4, the first flip flop output 416 is connected to a gate voltage input (V_{Gate}) 421, a precharger 420 and a first TUT connection 431. The first TUT connection 431 is connected to a gate terminal (labeled as GT) of an NMOS TUT 430. A drain voltage output (V_{Drain}) 422 from the precharger 420 is connected to a second TUT connection 432. The second TUT connection 432 is connected to a drain terminal (labeled as DT) of the NMOS TUT 430. A capacitor 440 is connected to the drain voltage output (V_{Drain}) 422 at a first capacitor terminal 441. And, a second capacitor terminal 442 is connected to a ground 450. The drain voltage output (V_{Drain}) 422 is also inputted to a second inverter 460. The output of the second inverter 460 (labeled as Vₛₑₙₛₑ 401) is inputted to NOR gate 403 and to the second NAND gate 407, and is also an input to the output divider 470.

In the example of FIG. 4, the output divider 470 includes a third inverter 480, a second flip flop 490 and a fourth inverter 485. As shown in FIG. 4, Vₛₑₙₛₑ 401 is connected to a third inverter input 481 (i.e., input of the third inverter 480). The third inverter 480 includes a third inverter output 482 which is connected to a second clock input 491of the second flip flop 490. The output divider 470 may lower an output frequency in half and may also reduce duty cycle distortion in an output waveform. In one example, the output waveform is the relaxation oscillator waveform which is modified by, for example, lowering its associated relaxation oscillator frequency. The relaxation oscillator frequency is the reciprocal of the relaxation oscillator period. The output (labeled as out 495) of the output divider 470 is a modified relaxation oscillator waveform.

In one example, there may be zero or more output divider stages. In one example, the third inverter 480 may reduce loading on the second inverter 460. In one example, the first flip flop 415 and the second flip flop 490 are asynchronous reset flip flops that are held in a reset state when the measurement tile is not enabled.

One skilled in the art would understand that the components listed herein for the example NMOS digital relaxation oscillator 400 are examples and the types of components and/or its quantity may vary within the spirit and scope of the present disclosure. And, it is understood that other components (although not explicitly listed herein) may be included as part of the example NMOS digital relaxation oscillator 400. One skilled in the art would also understand that the connections of the various components as shown in the example of FIG. 4 are not exclusive. That is, other connections between the various components shown in FIG. 4 are also within the spirit and scope of the present disclosure.

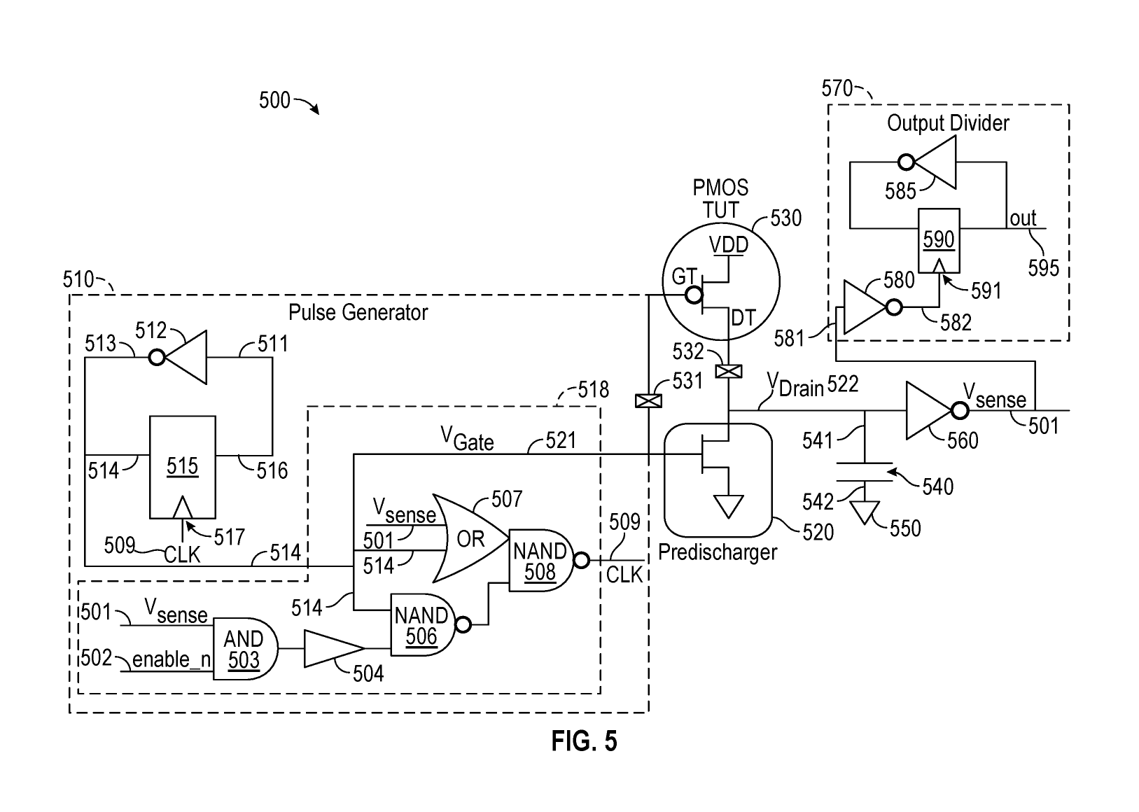

FIG. 5 an example of a positive channel metal oxide semiconductor (PMOS) digital relaxation oscillator 500. In one example, a pulse generator 510 includes a first inverter 512, a first flip flop 515 and a combinational logic 518. For example, a first inverter output 513 (i.e., output of the first inverter 512) is connected to a first flip flop input 514 (i.e., input of the first flip flop 515). For example, the first flip flop output 516 (i.e., output of the first flip flop 515) is connected to a first inverter input 511 (i.e., input of the first inverter 512). Also, the first flip flop 515 includes a first clock input 517 which is from an output of the combinational logic 518.

In one example, the first flip flop output 516 is a relaxation oscillator waveform. The relaxation oscillator waveform includes a relaxation oscillator frequency or a relaxation oscillator period. The relaxation oscillator frequency is a reciprocal of the relaxation oscillator period. And, the relaxation oscillator period is a reciprocal of the relaxation oscillator frequency.

In one example, combinational logic 518 may include one or more of the following components: an AND gate 503, a delay element 504, a first NAND gate 506, an OR gate 507, a second NAND gate 508, and a clock 509. In one example, the delay element 504 sets a precharger time delay by its delay characteristics. In the example of FIG. 5, the AND gate 503 includes a first AND gate input (Vₛₑₙₛₑ) 501 and a second AND gate input (enable) 502. In the example of FIG. 5, the first NAND gate 506 includes two inputs: a first input from the delay element 504 and a second input from the first flip flop input 514. In the example of FIG. 5, the OR gate 507 includes two inputs: a first input is from the Vₛₑₙₛₑ 501 and a second input is from the first flip flop input 514. In the example of FIG. 5, the second NAND gate 508 includes two inputs: a first input from the output of the NAND gate 506 and a second input from the output of the OR gate 507. In the example of FIG. 5, the clock 509 is an output of the third NAND gate 508, and the clock 509 is inputted to the first flip flop 515 through the first clock input 517.

As shown in FIG. 5, the first flip flop input 514 is connected to a gate voltage input (V_{Gate}) 521, a predischarger 520 and a first TUT connection 531 which is coupled to a gate terminal (labeled as GT) of a PMOS TUT 530. A drain voltage output (V_{Drain}) 522 from the predischarger 520 is connected to a second TUT connection 532. As shown in FIG. 5, the second TUT connection 532 is connected to a drain terminal (labeled as DT) of the PMOS TUT 530. A capacitor 540 is connected to the drain voltage output (V_{Drain}) 522 at a first capacitor terminal 541. And, the capacitor 540 is connected to a ground 550 at a second capacitor terminal 542. The drain voltage output (V_{Drain}) 522 is also inputted to a second inverter 560. The output of the second inverter 560 (labeled as Vₛₑₙₛₑ 501) is connected to the first AND gate input (also labeled as Vₛₑₙₛₑ 501). As shown in FIG. 5, the AND gate 503 is part of the combinational logic 513. And, the output of the second inverter 560 (labeled as Vₛₑₙₛₑ 501) is also an input to the output divider 570.

In the example of FIG. 5, the output divider 570 includes a third inverter 580, a second flip flop 590 and a fourth inverter 585. As shown in FIG. 5, Vₛₑₙₛₑ 501 is connected to a third inverter input 581 (i.e., input of the third inverter 580). The third inverter 580 includes a third inverter output 582 which is connected to a second clock input 591of the second flip flop 590. The output divider 570 may lower an output frequency in half and may also reduce duty cycle distortion in an output waveform. In one example, the output waveform is the relaxation oscillator waveform which is modified by, for example, lowering its associated relaxation oscillator frequency. The relaxation oscillator frequency is the reciprocal of the relaxation oscillator period. The output (labeled as out 595) of the output divider 570 is a modified relaxation oscillator waveform.

In one example, there may be zero or more output divider stages. In one example, the third inverter 580 may reduce loading on the second inverter 560. In one example, the first flip flop 515 and the second flip flop 590 are asynchronous reset flip flops that are held in a reset state when the measurement tile is not enabled.

One skilled in the art would understand that the components listed herein for the example PMOS digital relaxation oscillator 500 are examples and the types of components and/or its quantity may vary within the spirit and scope of the present disclosure. And, it is understood that other components (although not explicitly listed herein) may be included as part of the example PMOS digital relaxation oscillator 500. One skilled in the art would also understand that the connections of the various components as shown in the example of FIG. 5 are not exclusive. That is, other connections between the various components shown in FIG. 5 are also within the spirit and scope of the present disclosure.

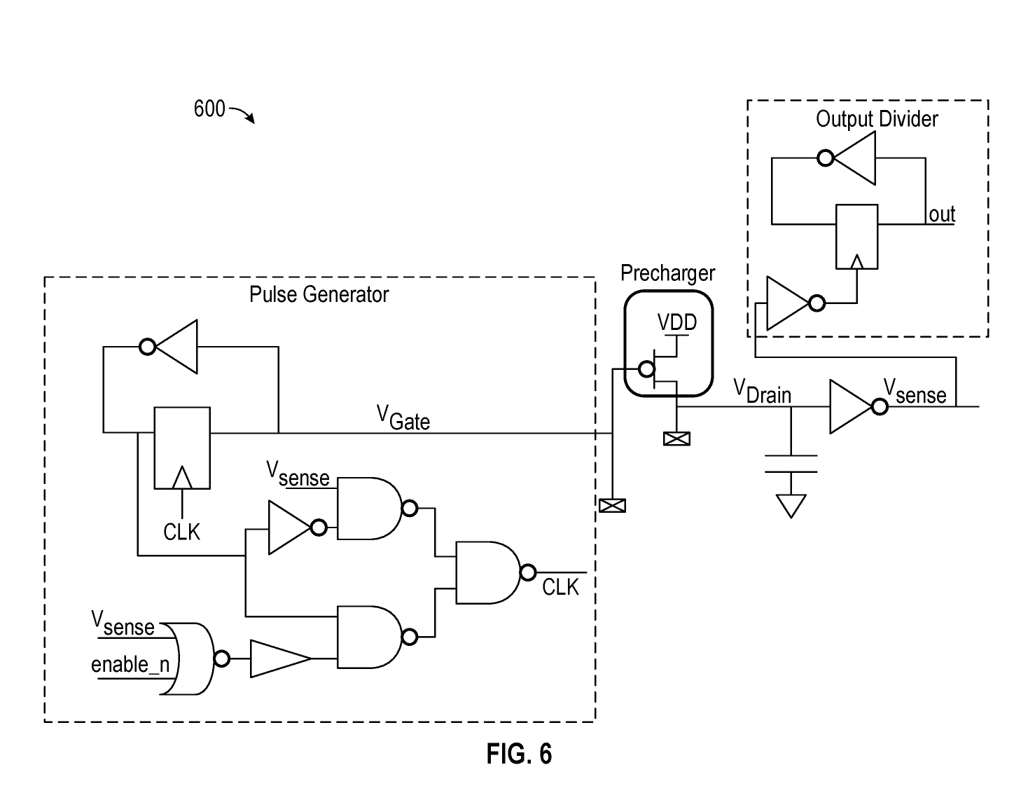

FIG. 6 illustrates an example 600 of a negative channel metal oxide semiconductor (NMOS) digital relaxation oscillator before connection to a plurality of NMOS transistors under test (TUTs). The example 600 shown in FIG. 6 includes some of the same components as those described in example 400 shown in FIG. 4, with the exception that the example 600 does not include the NMOS TUT 430. For the sake of brevity, some of the same components in FIG. 6 as those with FIG. 4 are not explicitly described herein but are shown in FIG. 6.

One skilled in the art would understand that the components for the example 600 are examples and the types of components and/or its quantity may vary within the spirit and scope of the present disclosure. And, it is understood that other components (although not explicitly listed herein) may be included as part of the example 600. One skilled in the art would also understand that the connections of the various components as shown in the example of FIG. 6 are not exclusive. That is, other connections between the various components shown in FIG. 6 are also within the spirit and scope of the present disclosure.

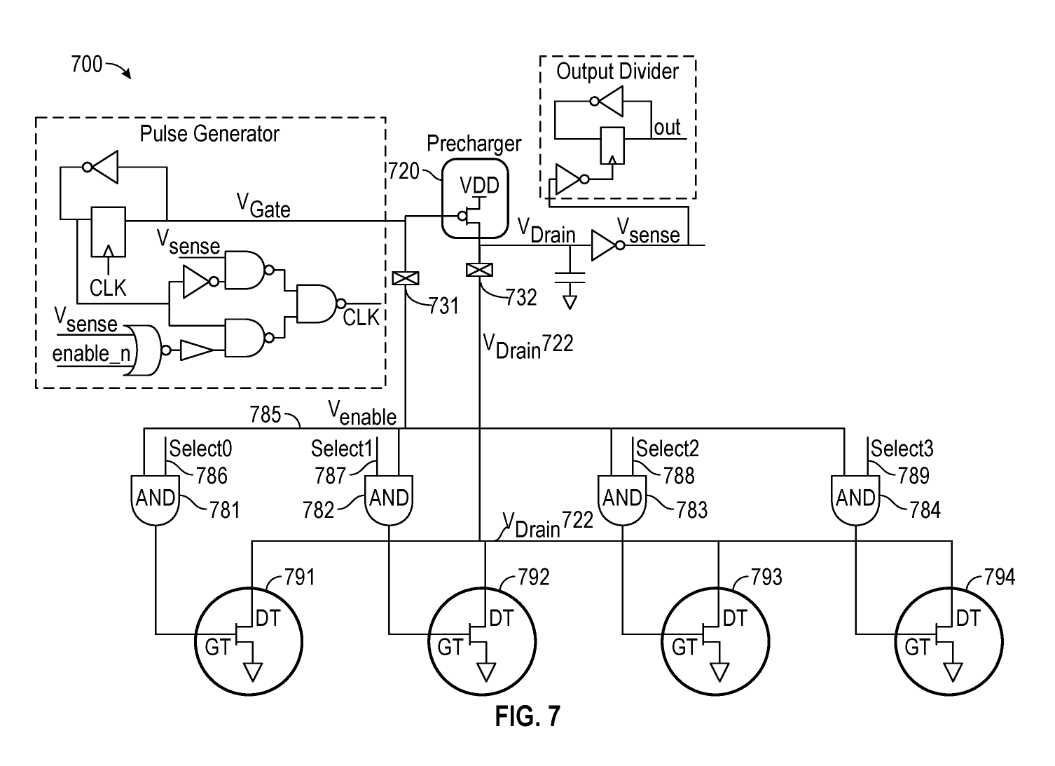

FIG. 7 illustrates an example 700 of a negative channel metal oxide semiconductor (NMOS) digital relaxation oscillator after connection to a plurality of NMOS transistors under test (TUTs) 791, 792, 793, 794. The example 700 shown in FIG. 7 includes some of the same components as those described in example 400 shown in FIG. 4. For the sake of brevity, some of the same components in FIG. 7 as those with FIG. 4 are not explicitly described herein but are shown in FIG. 7. In addition, example 700 includes the addition of a plurality of NMOS transistors under test (TUTs). As shown in FIG. 7, the NMOS digital relaxation oscillator may be connected to two or more NMOS TUTs, for example, to four NMOS TUTs 791,792, 793, 794 in the example 700 of FIG. 7.

In one example, a first TUT connection 731 is connected to a gate voltage input (V_{Gate}) at a precharger 720. The first TUT connection 731 provides an enable signal (V_{enable}) 785. As shown in FIG. 7, the enable signal (V_{enable}) 785 is inputted to a first AND gate 781, a second AND gate 782, a third AND gate 783, and a fourth AND gate 784. In the example of FIG. 7, the enable signal (V_{enable}) 785 is a first input to each of the AND gates 781, 782, 783, 784. In addition, a first select signal (Select0) 786 is provided as a second input to the first AND gate 781, a second select signal (Select1) 787 is provided as a second input to the second AND gate 782, a third select signal (Select2) 788 is provided as a second input to the third AND gate 783, and a fourth select signal (Select3) 789 is provided as a second input to the fourth AND gate 784. In one example, the select signals (Select0, Select1, Select2, Select3) are used to select one of the four NMOS TUTs for measurement of its current. One skilled in the art would understand that although four NMOS TUTs are shown herein, other quantities of NMOS TUTs and/or other types of TUTs (such as but not limited to PMOS TUTs) may be used within the spirit and scope of the present disclosure. In one example, PMOS TUTs may be connected using OR gates instead of AND gates.

In one example, an output of the first AND gate 781 is connected to a gate terminal (labeled as GT) of first NMOS TUT 791. In one example, an output of the second AND gate 782 is connected to a gate terminal (labeled as GT) of second NMOS TUT 792. In one example, an output of the third AND gate 783 is connected to a gate terminal (labeled as GT) of third NMOS TUT 793. In one example, an output of the fourth AND gate 784 is connected to a gate terminal (labeled as GT) of fourth NMOS TUT 794.

In example 700, a drain voltage output (V_{Drain}) 722 from the predischarger 720 is connected to a second TUT connection 732. As shown in FIG. 7, the drain voltage output (V_{Drain}) 722 (and hence the second TUT connection 732) is connected to a drain terminal (labeled as DT) of the first NMOS TUT 791. As shown in FIG. 7, the drain voltage output (V_{Drain}) 722 (and hence the second TUT connection 732) is also connected to a drain terminal (labeled as DT) of the second NMOS TUT 792. As shown in FIG. 7, the drain voltage output (V_{Drain}) 722 (and hence the second TUT connection 732) is also connected to a drain terminal (labeled as DT) of the third NMOS TUT 793. As shown in FIG. 7, the drain voltage output (V_{Drain}) 722 (and hence the second TUT connection 732) is also connected to a drain terminal (labeled as DT) of the fourth NMOS TUT 794.

In one example, if the enable signal (V_{enable}) 785 is in a HIGH state, then selection of one of the plurality of NMOS TUTs (i.e., 791, 792, 793, 794) for digital current measurement may be made by assertion of one of a plurality of select signals: first select signal (Select0) 786, second select signal (Select1) 787, third select signal (Select2) 788, third select signal (Select3) 789. For example, assertion of Select0 786 selects first NMOS TUT 791, assertion of Select1 787 selects second NMOS TUT 792, assertion of Select2 788 selects third NMOS TUT 793, and assertion of Select3 789 selects fourth NMOS TUT 794. In one example, assertion of a select signal means setting the select signal to a HIGH state.

One skilled in the art would understand that the components for the example 700 are examples and the types of components and/or its quantity may vary within the spirit and scope of the present disclosure. And, it is understood that other components (although not explicitly listed herein) may be included as part of the example 700. One skilled in the art would also understand that the connections of the various components as shown in the example of FIG. 7 are not exclusive. That is, other connections between the various components shown in FIG. 7 are also within the spirit and scope of the present disclosure.

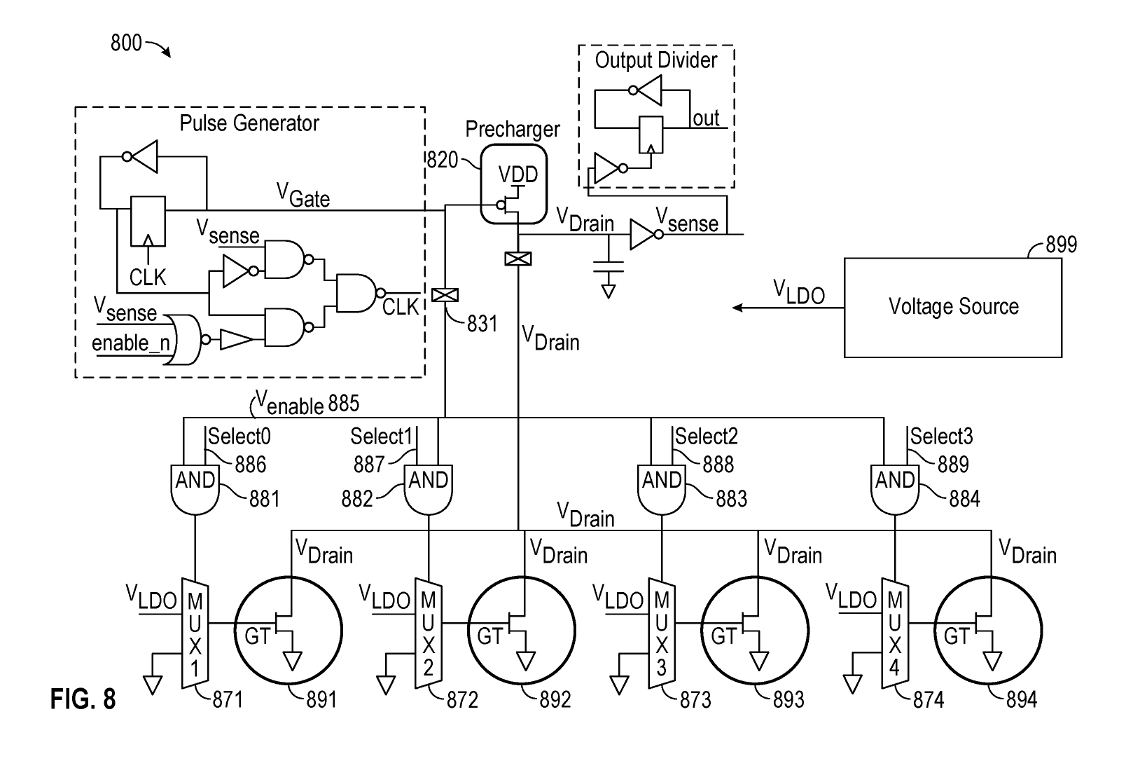

FIG. 8 illustrates an example of a negative channel metal oxide semiconductor (NMOS) digital relaxation oscillator after connection to a plurality of NMOS transistors under test (TUTs) 891, 892, 893, 894 and with an external voltage source 899. In one example, FIG. 8 includes some of the same components as those described in FIG. 7 but with the addition of a plurality of multiplexers (e.g., mux1 871, mux2 872, mux3 873, and mux4 874) and the addition of an external voltage source 899. For the sake of brevity, some of the same components in FIG. 8 as those with FIG. 7 are not explicitly described herein but are shown in FIG. 8. In one example, the component arrangement of example 800 may be used to control analog voltage level to the gate terminals of the plurality of NMOS TUTs 891, 892, 893, 894. In one example, the external voltage source 899 provides an analog voltage level (labeled as VLDO) to inputs to multiplexer (mux1) 871, multiplexer (mux2) 872, multiplexer (mux3) 873, and multiplexer (mux4) 874. In addition, each of the plurality of multiplexers (i.e., mux1 871, mux2 872, mux3 873 and mux4 874) include a second input that is set to ground (as shown in FIG. 8). The external voltage source 899 may be used to measure the TUT with the gate terminal at a voltage that is the same or different from the drain terminal voltage. Measurements at multiple gate voltages can be used to separate voltage-dependent contributions to the drain current, such as mobility and threshold voltage.

In one example, a first TUT connection 831 is connected to a gate voltage input (V_{Gate}) at a precharger 820. The first TUT connection 831 provides an enable signal (V_{enable}) 885. In one example, if the enable signal (V_{enable}) 885 is in a HIGH state, then selection of one of the plurality of multiplexers (e.g., mux1 871, mux2 872, mux3 873, and mux4 874) for control of analog voltage level to the gate terminals (labeled as GT) of the plurality of NMOS TUTs 891, 892, 893, 894 may be made by assertion of one of a plurality of select signals: Select0 886, Select1 887, Select2 888, Select3 889. For example, assertion of Select0 886 selects analog voltage level VLDO to a gate terminal (labeled as GT) of first NMOS TUT 891, assertion of Select1 887 selects analog voltage level VLDO to a gate terminal (labeled as GT) of second NMOS TUT 892, assertion of Select2 888 selects analog voltage level VLDO to a gate terminal (labeled as GT) of third NMOS TUT 893, and assertion of Select3 889 selects analog voltage level VLDO to a gate terminal (labeled as GT) of fourth NMOS TUT 894. In one example, assertion of a select signal means setting the select signal to a HIGH state. Similar to FIG. 7, the example 800 of FIG. 8 also includes AND gates 881, 882, 882, 884 as shown.

In one example, a design goal is a measurement circuit which can measure a transistor under test (TUT) current and produce a digital measurement of the TUT current. In one example, the measurement circuit is compatible with a standard cell integrated circuit environment. For example, there may be an even number of standard cell rows and the design may be in a standard cell style. For example, the measurement circuit may be small and easy to integrate to allow placement throughout a standard cell design and may be designed to attach onto a transistor under test (TUT) tile. In one example, a minimum number of patterns on a die is approximately 10,000. One skilled in the art would understand that the number of patterns at approximately 10,000 is only an example and that other minimum numbers of the patterns not mentioned herein may also be within the spirit and scope of the present disclosure.

Disclosed herein in one aspect is an in-situ digital measurement circuit which converts a transistor under test (TUT) current or inverse current to a relaxation oscillator parameter. For example, the TUT current is denoted as I and the TUT inverse current is denoted as I⁻¹, where 1/I=I⁻¹. In one example, the relaxation oscillator parameter may be either a relaxation oscillator frequency F_{osc} or a relaxation oscillator period T_{osc}. In one example, the relaxation oscillator frequency F_{osc} is the reciprocal of the relaxation oscillator period T_{osc}, that is, F_{osc}=1/T_{osc}. In one example, the relaxation oscillator frequency F_{osc} or the relaxation oscillator period T_{osc} is a function of the transistor under test current I or inverse current I⁻¹. A counter circuit may be used to measure the relaxation oscillator frequency F_{osc}, or its period T_{osc}, to produce a digital representation of the transistor under test current I or inverse current I⁻¹. More specifically, the counter circuit measures the relaxation oscillator period T_{osc} which is linearly related to the transistor under test inverse current I⁻¹. Thus, the counter circuit output may be used to determine the TUT current. With this in-situ digital measurement circuit, transistor current may be tracked throughout the device life cycle to monitor performance variation over process, voltage and temperature (PVT).

In one example, an all-digital measurement tile on an integrated circuit or semiconductor wafer is used which places a TUT within a relaxation oscillator circuit where the relaxation oscillator frequency F_{osc} or the relaxation oscillator period T_{osc} depends on the TUT current I or TUT inverse current I⁻¹. In one example, the TUT may be a negative metal oxide semiconductor (NMOS) transistor or a positive metal oxide semiconductor (PMOS). In one aspect, an NMOS measurement tile is used to monitor NMOS transistors and a PMOS measurement tile is used to monitor PMOS transistors. The elements of the measurement tile may include the TUT, a pre-charger and a capacitor arranged in a feedback loop to operate as an oscillator as the capacitor charges and discharges. The pre-charger time constant may be determined by a precharger time delay to facilitate measurement calibration.

In one example, a conversion equation relates quantitatively the relaxation oscillator period T_{osc} to the TUT current I or TUT inverse current I⁻¹. In one example, the conversion equation has the form of a linear equation of relaxation oscillator period T_{osc} vs. TUT inverse current I⁻¹:

T_{osc}=C ΔV I⁻¹+t_{ckt}

where T_{osc}=relaxation oscillator period=1/oscillator frequency (F_{osc}),

and t_{ckt}=circuit offset time due to the precharger time delay.

In one example, C is a capacitance value of the capacitor and ΔV is the change of voltage of the capacitor, and C ΔV is the slope of the linear equation. In one example, the relaxation oscillator period T_{osc} is a characteristic of a relaxation oscillator waveform, wherein the relaxation oscillator waveform is based on turning OFF and turning ON of the TUT.

In one example, since the conversion equation includes a slope C ΔV and the current offset time t_{ckt} which are process dependent, a calibration process may be needed to minimize the transistor current measurement error. In one example, the calibration process may require two known currents to fit the linear equation of the relaxation oscillator period T_{osc} vs. TUT inverse current I⁻¹ to an absolute current value. In one example, process dependent means that a manufacturing technique used to produce the TUT may affect the slope C ΔV and the current offset time t_{ckt}.

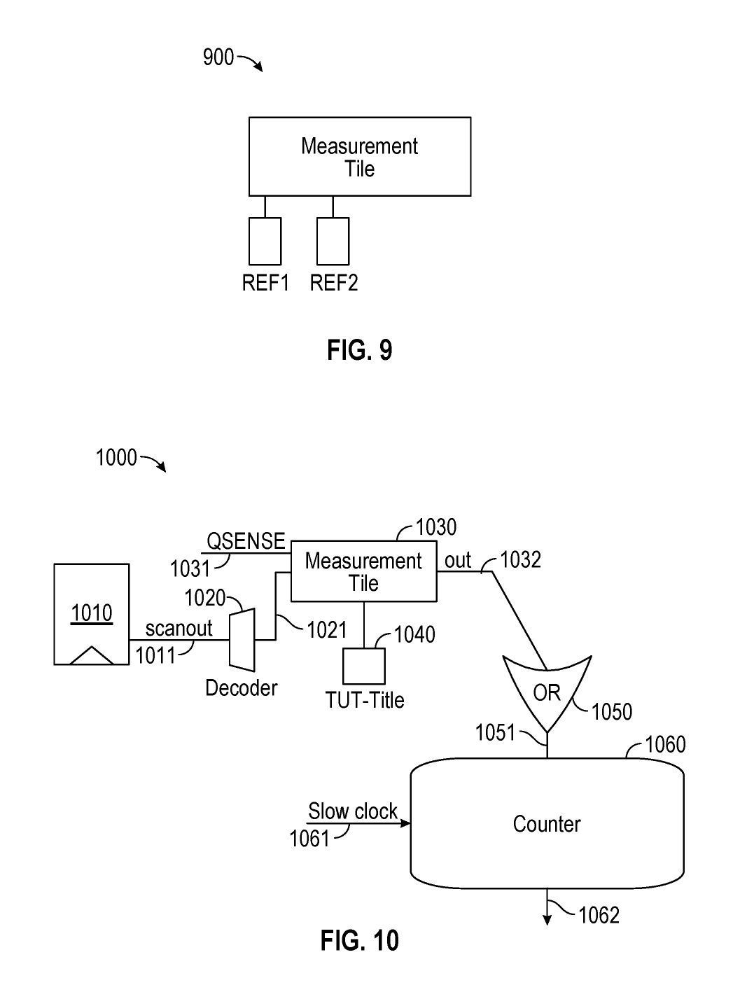

For example, the calibration process may use a current mirror replication of a reference current to provide two known currents. In a first calibration method, current of reference transistors may be determined by physical measurement of current of test structure transistors which have identical layout to the reference transistors. In one example, the reference transistors may have previously determined currents, or known currents. In one example, the quantity of reference transistors is two. FIG. 9 illustrates an example of a measurement tile 900 with two reference transistors, Ref1, Ref2. The measurement tile 900 may be used to support a plurality of TUTs (not shown).

In a second calibration method, a circuit simulation model of the reference transistors using a circuit simulation tool may be used to extract circuit parameters for the reference transistors using identical transistors configured as a ring oscillator. An example of a circuit simulation tool is SPICE. SPICE is known as Simulation Program with Integrated Circuit Emphasis and is a general-purpose, open source analog electronic circuit simulator which is used in integrated circuit design to check the integrity of the integrated circuit designs.

For example, if the ring oscillator frequency or period is measured at a plurality of supply voltages and compared to the circuit simulation model, sensitivity to the circuit simulation tool parameters may be determined to obtain a sensitivity matrix [S] and another circuit simulation model of the reference transistors may be generated. Next, the circuit simulation model may be used to create a linear system of equations of the form, for example:

[S][H]=[F], where

[H]=circuit simulation model vector,

[S]=sensitivity matrix, and

[F]=ring oscillator frequency vector.

In one example, the linear system of equations may be solved either analytically or via simulation techniques.

In one example, the measurement circuit measures average transistor current as the drain voltage varies from maximum drain voltage VDD to half maximum drain voltage VDD/2 (e.g., for NMOS transistors) and as the gate voltage varies from VDD to VDD/2. For example, there are two strategies for the measurement circuit. A first strategy may be placing measurement tiles around a circuit die under test to sample local layout variations around the circuit die under test. A second strategy may be placing measurement tiles in a layout pattern without consideration of a local layout environment. In one example, the second strategy may cluster measurement tiles in low utilization areas.

In one example, a test time Tₜₑₛₜ for the measurement circuit depends on a sum of measurement time Tₘₑₐₛ and a scan time T_{scan}. The measurement time Tₘₑₐₛ depends on a product of a reference clock period T_{ref}, a number of reference clock periods N_{ref} per TUT measurement, and a total number of TUTs being measured N_{T}. The scan time T_{scan} depends on a product of a scan clock period Tₛ, a number of scans Nₛ, and the total number of TUTs being measured N_{T}. For example, the test time Tₜₑₛₜ may be expressed as:

Tₜₑₛₜ=T_{meas.}+T_{scan}

Tₜₑₛₜ=T_{ref}N_{ref}N_{T.}+TₛNₛN_{T}.

In one example, if the reference clock period T_{ref} is 25 ns (i.e., reciprocal of 40 MHz), the number of reference clock periods N_{ref} is 500, the scan clock period Tₛ is 20 ns (i.e., reciprocal of 50 MHz), the number of scans Nₛ is 512, the total number of TUTs being measured N_{T} is 10,000, then the test time Tₜₑₛₜ is:

Tₜₑₛₜ=(25 ns) (500)(10,000)+(20 ns) (512) (10,000)

Tₜₑₛₜ=125 ms+102.4 ms=227.4 ms.

In one example, the test time Tₜₑₛₜ is proportional to the total number of TUTs being measured N_{T}.

FIG. 10 illustrates an example measurement circuit 1000 for generating a digital measurement of transistor under test (TUT) current. For example, a flip flop 1010 may generate a scanout signal 1011. In one example, the scanout signal 1011 may be a coded signal which designates one TUT out of a plurality of TUTs for digital measurement. The scanout signal 1011 may be sent to a decoder 1020. In one example, the decoder 1020 decodes the scanout signal 1011 to produce a decoded scanout signal 1021. Next, the decoded scanout signal 1021 may be a first input to a measurement tile 1030. In addition, a QSENSE signal A101 may be a second input to measurement tile 1030. In one example, measurement tile 1030 is connected to TUT tile 1040. In one example, the measurement tile 1030 is used to measure the current of TUT tile 1040. Next, the measurement tile 1030 may have an output signal (labeled as out) 1032 which is sent as an input to OR gate 1050. In one example, the output signal (labeled as out) 1032 is a periodic waveform with a period dependent on current of TUT tile 1040. Next, an OR gate output 1051 (i.e., output of the OR gate 1050) is sent to counter 1060. In one example, counter 1060 counts the number of periods of the output signal (labeled as out) 1032 to produce a period count 1062. In one example, the period count 1062 is measured relative to a local slow clock 1061. In one example, the period count 1062 is related to the current of TUT tile 1040. In one example, the period count 1062 is a digital current measurement of the TUT. In one example, the counter 1060 is synthesizable. Although the TUT tile 1040 is shown as separate from the measurement tile 1030, in another example, the measurement tile 1030 may include within it the TUT tile.

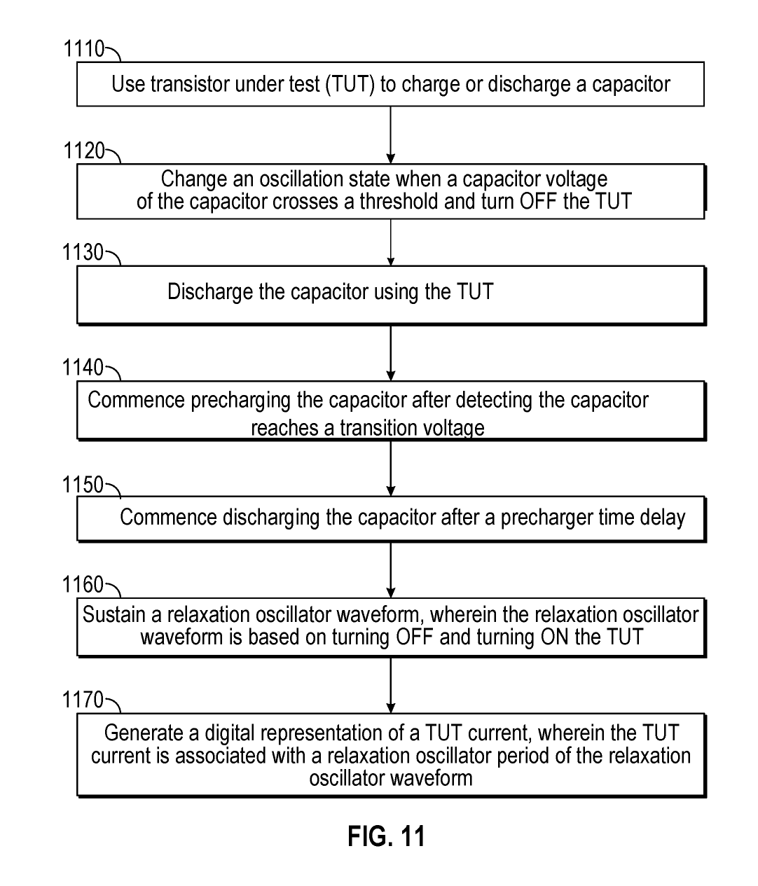

FIG. 11 illustrates an example flow diagram 1100 for digital current measurement for monitoring an in-situ device. In block 1110, use a transistor under test (TUT) to charge or discharge a capacitor, wherein the capacitor is coupled to the TUT. In one example, the TUT is a NMOS transistor. In another example, the TUT is a PMOS transistor. In one example, the TUT charges or discharges the capacitor through a drain voltage of the TUT.

In block 1120, change an oscillation state when a capacitor voltage of the capacitor crosses a threshold and turns OFF the TUT. In one example, the threshold is predetermined based on one or more characteristics of the TUT. In one example, the threshold is half of a maximum value of the drain voltage of the TUT. In one example, a pulse generator turns OFF the TUT. In one example, changing the oscillation state is to change from one voltage level to another voltage level. In one example, the threshold is determined by the switching point of an inverter connected to the capacitor. The inverter may act as a comparator and may change its state when the capacitor voltage is approximately at half the drain voltage of the TUT. In one example, the drain voltage is also known as the supply voltage of the TUT.

In block 1130, discharge the capacitor using the TUT.

In block 1140, commence precharging the capacitor after detecting the capacitor reaches a transition voltage. In one example, the transition voltage is a half maximum value of the drain voltage of the TUT. In one example, the detecting is performed by the inverter. In one example, the precharging is performed by the pulse generator.

In block 1150, commence discharging the capacitor after a precharger time delay. In one example, the precharger time delay is chosen to ensure an adequate precharge time and to ensure that the precharge time is independent of precharger strength and variation. In one example, the precharge for an NMOS sensor is made from several PMOS transistors. The more PMOS transistors that are used, the faster the capacitor will precharge because there are more transistors providing current. Similarly, if the PMOS transistors use a lower threshold voltage, a shorter channel length, or a larger width, more total current will be available to precharge the capacitor, and the capacitor will precharge faster. That is, the precharger strength refers to the amount of current the precharger provides. In one example, the precharger strength may depend on transistor length, width, threshold voltage and quantity. The strength of the precharger refers to the amount of current it can provide, and therefore refers to width, length, threshold voltage, and number of transistors. In another example, variation may refer to normal manufacturing variation which results in differences in transistor length, width and threshold voltage for nominally identical transistors.

In block 1160, sustain a relaxation oscillator waveform, wherein the relaxation oscillator waveform is based on turning OFF and turning ON the TUT. In one example the relaxation oscillator waveform includes a relaxation oscillator period which is a reciprocal of a relaxation oscillator frequency. In one example, the pulse generator sustains the relaxation oscillator waveform by an inverting feedback loop and an ON/OFF state of the TUT. The ON/OFF state is an indication of whether the TUT is turned ON or turned OFF. In one example, the inverting feedback loop includes a flip flop coupled to an inverter (e.g., a first flip flop 315 and a first inverter 312 as shown in FIG. 3). For example, a flip flop output is connected to an inverter input (e.g., a first flip flop output 316 is connected to a first inverter input 311), and an inverter output is connected to a first flip flop input (e.g., a first inverter output 313 is connected to a first flip flop input 314) to define the inverting feedback loop.

In block 1170, generate a digital representation of a TUT current, wherein the TUT current is associated with a relaxation oscillator period of the relaxation oscillator waveform. In one example, a counter is used to generate the digital representation of the TUT current. In one example, a conversion equation is used to convert the relaxation oscillator period to an inverse current of the TUT. The inverse current is a reciprocal of the TUT current. In one example, the conversion equation is as follows:

T_{osc}=C ΔV I⁻¹+t_{ckt}

where T_{osc}=relaxation oscillator period=1/oscillator frequency (F_{osc}),

and t_{ckt}=circuit offset time due to a precharger time delay.

In one example, the digital current measurement (as disclosed in FIG. 11) may monitor a plurality of NMOS and/or PMOS transistors in a in-situ device by using one or more multiplexers to select one transistor sequentially for current measurement. In an example sequence for the case of an NMOS TUS):
1. The TUT discharges the load capacitor
2. The sense inverter detects that the load capacitor voltage it at half the drain voltage (a.k.a., supply voltage)
3. The pulse generator changes state to PRECHARGE
4. After a precharger time delay, the pulse generator changes state to DISCHARGE
5. The purpose of the precharge timer is to ensure an adequate precharge time, and to ensure that the precharge time is not dependent on the strength of the precharge PMOS, therefore making the precharge time independent of variation in the precharge PMOS

In one aspect, one or more of the steps for providing digital current measurement for in-situ device monitoring in FIG. 11 may be executed by one or more processors which may include hardware, software, firmware, etc. In one aspect, one or more of the steps in FIG. 11 may be executed by one or more processors which may include hardware, software, firmware, etc. The one or more processors, for example, may be used to execute software or firmware needed to perform the steps in the flow diagram of FIG. 11. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a computer-readable medium. The computer-readable medium may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer.

The computer-readable medium may also include, by way of example, a carrier wave, a transmission line, and any other suitable medium for transmitting software and/or instructions that may be accessed and read by a computer. The computer-readable medium may reside in the processing system, external to the processing system, or distributed across multiple entities including the processing system. The computer-readable medium may be embodied in a computer program product. By way of example, a computer program product may include a computer-readable medium in packaging materials. The computer-readable medium may include software or firmware for digital current measurement for in-situ device monitoring. Those skilled in the art will recognize how best to implement the described functionality presented throughout this disclosure depending on the particular application and the overall design constraints imposed on the overall system.

Any circuitry included in the processor(s) is merely provided as an example, and other means for carrying out the described functions may be included within various aspects of the present disclosure, including but not limited to the instructions stored in the computer-readable medium, or any other suitable apparatus or means described herein, and utilizing, for example, the processes and/or algorithms described herein in relation to the example flow diagram.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. For instance, a first die may be coupled to a second die in a package even though the first die is never directly physically in contact with the second die. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

What is claimed is:

1. A method for digital current measurement for monitoring an in-situ device, the method comprising:
using a transistor under test (TUT) to charge or discharge a capacitor;
changing an oscillation state when a capacitor voltage of the capacitor crosses a threshold and turning OFF the TUT;
discharging the capacitor using the TUT;
commencing precharging the capacitor after detecting the capacitor reaches a transition voltage;
commencing discharging the capacitor after a precharger time delay;
sustaining a relaxation oscillator waveform, wherein the relaxation oscillator waveform is based on turning OFF and turning ON the TUT; and
generating a digital representation of a TUT current, wherein the TUT current is associated with a relaxation oscillator period of the relaxation oscillator waveform.

2. The method of claim 1, wherein the threshold is half of a maximum value of a drain voltage of the TUT.

3. The method of claim 1, further comprising using a conversion equation to convert the relaxation oscillator period to an inverse current of the TUT.

4. The method of claim 3, wherein the inverse current of the TUT is a reciprocal of the TUT current.

5. The method of claim 3, wherein the conversion equation has the form of a linear equation.

6. The method of claim 3, wherein the conversion equation is as follows:
T_{osc}=C ΔV I⁻¹+t_{ckt}
wherein T_{osc} is the relaxation oscillator period, C ΔV is a slope of the conversion equation, and t_{ckt} is a circuit offset time due to a precharger time delay.

7. The method of claim 6, wherein C is a capacitance value of the capacitor and ΔV is the change of voltage of the capacitor.

8. The method of claim 3, wherein the conversion equation is based on a calibration process which uses a reference current or a circuit simulation model.

9. The method of claim 1, wherein the in-situ device includes a plurality of negative channel metal oxide semiconductor (NMOS) transistors.

10. The method of claim 1, wherein the in-situ device includes a plurality of positive channel metal oxide semiconductor (PMOS) transistors.

11. The method of claim 1, wherein a precharger is used to precharge the capacitor.

12. A measurement tile comprising:
a transistor under test (TUT);
a pulse generator to sustain a relaxation oscillator waveform with a relaxation oscillator period associated with an inverse current of the TUT;
a capacitor coupled to the TUT;
a precharger coupled to the capacitor and to the TUT, the precharger for charging the capacitor and the TUT for charging or discharging the capacitor, wherein the relaxation oscillator waveform is based on turning OFF and turning ON the TUT in accordance with discharging and charging the capacitor.

13. The measurement tile of claim 12, further comprising an output divider to output a modified relaxation oscillator waveform, wherein the modified relaxation oscillator waveform is the relaxation oscillator waveform with the relaxation oscillator period modified, and wherein the output divider is coupled to the capacitor.

14. The measurement tile of claim 13, wherein the modified relaxation oscillator waveform is inputted to a counter, the counter to output a digital current measurement of the TUT.

15. The measurement tile of claim 12, wherein the pulse generator comprises:
a combinational logic to provide a clock input in accordance with the TUT;
a flip flop to receive the clock input; and
an inverter coupled to the flip flop to form an inverting feedback loop.

16. The measurement tile of claim 15, wherein the inverting feedback loop sustains the relaxation oscillator waveform in accordance with an ON/OFF state of the TUT.

17. The measurement tile of claim 16, wherein a drain voltage output from the precharger is coupled to a drain terminal of the TUT.

18. The measurement tile of claim 17, wherein the drain voltage output is coupled to the capacitor at a first capacitor terminal.

19. The measurement tile of claim 18, wherein the drain voltage output is inputted to the combinational logic and is inputted to an output divider, wherein the output divider outputs a modified relaxation oscillator waveform.

20. The measurement tile of claim 19, wherein the modified relaxation oscillator waveform is the relaxation oscillator waveform with the relaxation oscillator period modified.

21. The measurement tile of claim 20, wherein the combinational logic comprises one or more of an AND gate, a NAND gate, an OR gate and/or a NOR gate coupled to each other in accordance to whether the TUT is a negative channel metal oxide semiconductor (NMOS) TUT or a positive channel metal oxide semiconductor (PMOS) TUT.

22. The measurement tile of claim 21, wherein the modified relaxation oscillator waveform is inputted to a counter, the counter to output a digital current measurement of the TUT.

23. The measurement tile of claim 21, wherein the transistor under test (TUT) comprises a plurality of transistors under test (TUTs).

24. The measurement tile of claim 23, wherein a select signal is used to select one of the plurality of transistors under test (TUTs) for current measurement.

25. An apparatus for digital current measurement for monitoring an in-situ device, the apparatus comprising:
means for using a transistor under test (TUT) to charge or discharge a capacitor;
means for changing an oscillation state when a capacitor voltage of the capacitor crosses a threshold and turning OFF the TUT;
means for discharging the capacitor using the TUT;
means for commencing precharging the capacitor after detecting the capacitor reaches a transition voltage;
means for commencing discharging the capacitor after a precharger time delay;
means for sustaining a relaxation oscillator waveform, wherein the relaxation oscillator waveform is based on turning OFF and turning ON the TUT; and
means for generating a digital representation of a TUT current, wherein the TUT current is associated with a relaxation oscillator period of the relaxation oscillator waveform.

26. A computer-readable medium storing computer executable code, operable on a device comprising at least one processor and at least one memory coupled to the at least one processor, wherein the at least one processor is configured to implement digital current measurement for monitoring an in-situ device, the computer executable code comprising:
instructions for causing a computer to charge or discharge a capacitor using a transistor under test (TUT);
instructions for causing the computer to change an oscillation state when a capacitor voltage of the capacitor crosses a threshold and turning OFF the TUT;
instructions for causing the computer to discharge the capacitor using the TUT;
instructions for causing the computer to commence precharging the capacitor after detecting the capacitor reaches a transition voltage;
instructions for causing the computer to commence discharging the capacitor after a precharger time delay;
instructions for causing the computer to sustain a relaxation oscillator waveform, wherein the relaxation oscillator waveform is based on turning OFF and turning ON the TUT; and
instructions for causing the computer to generate a digital representation of a TUT current, wherein the TUT current is associated with a relaxation oscillator period of the relaxation oscillator waveform.
